(19) United States
(12) Patent Application Publication
(10) Pub. No.: US 2002/0166229 A1
(43) Pub. Date: Nov. 14, 2002

(54) METHODS AND APPARATUS FOR WITHDRAWAL AND INSERTION OF POWERED MODULES

(75) Inventors: Martin Peltz, Charlottesville, VA (US); Kenneth Knight, Charlottesville, VA (US); Bobby L. Hicks, Ruckersville, VA (US); Charles A. Maddox, Barboursville, VA (US); Wallace E. Watson Jr., Crozet, VA (US); William L. Dalton, Charlottesville, VA (US); Chris P. Cuthbert, Keene, VA (US); Jiankun Hu, Allentown, PA (US); Michael A. Kittel, Earlysville, VA (US); Colin A. Pape, Barboursville, VA (US)

Correspondence Address: John S. Beulick, Armstrong Teasdale, LLP, 1 Metropolitan Square, Suite 2600, St. Louis, MO, 63102, US, jbeulick@armstrongteasdale.com, (314) 621-5070, (314) 621-5065

(73) Assignee: General Electric Company, Schenectady, 12345 (US)

(21) Appl. No.: 09/465,484

(22) Filed: Dec. 16, 1999

(51) Int. Cl. H05K 3/30

(52) U.S. Cl. 29/837; 29/832

(57) ABSTRACT

### Abstract of Disclosure

A method for connecting a circuit module to a powered electronic system by inserting connector pins having different lengths into the powered electronic system to control current draw of the circuit module and to prevent large inrush currents into the circuit module.

### Background of Invention

This invention relates generally to the insertion and removal of modules in an electronic system and more specifically to methods and apparatus for controlling the power up of inserted modules.

Known electronic systems are extensively used in process control applications. These electronic systems are usually modular, that is, a central processing unit (CPU) communicates with a series of replaceable modules, sometimes called input/output (I/O) modules that are connected to the CPU in a bus arrangement, sometimes referred to as a backplane. I/O modules are configured in multiple configurations and perform a variety of functions depending upon the specific input/output requirements of a particular application. In one aspect of process control, the CPU monitors inputs and outputs from various I/O modules.

When a module fails, it is sometimes necessary to shut down the entire system in order to replace the one defective module. The entire system is shutdown because inserting the module into a powered system creates a possibility that instantaneous or inrush currents into the module being inserted will cause a temporary overload and therefore effect operation of other devices already powered and operating.

### Summary of Invention

Thus it is advantageous to have methods and apparatus that allow for replacement of a module in a powered electronic system without excessive inrush currents overloading the system as the module is inserted. It is also advantageous to verify that the proper type of module has been inserted into the powered electronic system before the module is allowed to communicate with the powered electronic system.

In an exemplary embodiment, elongated connector pins are included on circuit connectors of I/O modules of the powered electronic system. The elongated connector pins allow the I/O modules to draw current from the powered electronic system in a more controlled fashion and prevent large inrush currents when the I/O modules are inserted into a backplane of the powered electronic system that is operating. The elongated connector pins have multiple lengths, which allow the I/O module to be pre-charged before it is directly powered by the electronic system.

### Brief Description of Drawings

Figure 1 is a schematic diagram of an electronic system.

Figure 2 is a top external view of a connector of a known pin arrangement with pin lengths according to one embodiment of the present invention.

Figure 3 is a side view of the connector shown in Figure 2.

Figure 4 is a circuit schematic drawn to illustrate the electrical effect of using the connector shown in Figure 2.

Figure 5 is an exploded perspective view of an input/output module.

Figure 6 is a perspective view of an input/output module cover.

Figure 7 is a perspective view of multiple circuit cards from an I/O module.

Figure 8 is a flowchart illustrating an inserted I/O module power-up sequence.

Figure 9 illustrates a bottom perspective view of an I/O module carrier.

Figure 10 illustrates a top perspective view of the I/O module carrier shown in Figure 9.

Figure 11 shows a perspective view of an I/O module.

### Detailed Description

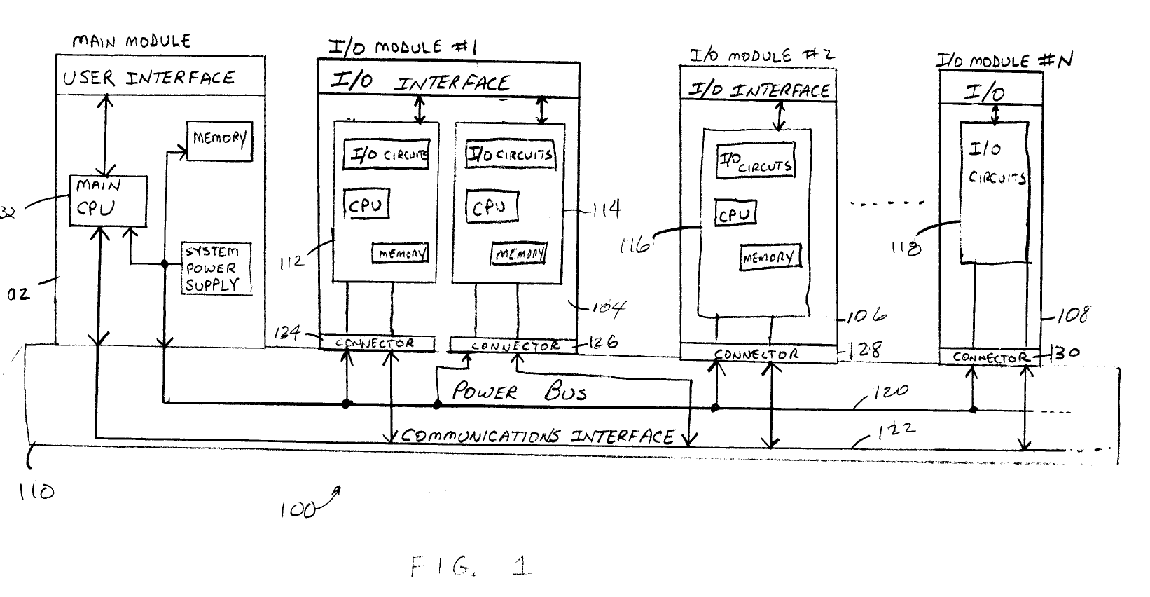

Figure 1 is a schematic illustration of an electronic system 100. Electronic system 100 includes a main module 102, a plurality of input/output (I/O) modules 104, 106, and 108, and a backplane 110. I/O module 104 includes two circuit cards 112 and 114, and I/O module 106 includes one circuit card 116. In addition, I/O module 108 includes circuit card 118. Each circuit card 112, 114, 116, and 118 connects to a power bus 120 and a communications interface 122 of electronic system backplane 110 through a plurality of connectors 124, 126, 128, and 130, respectively. Main module 102 includes a main CPU 132.

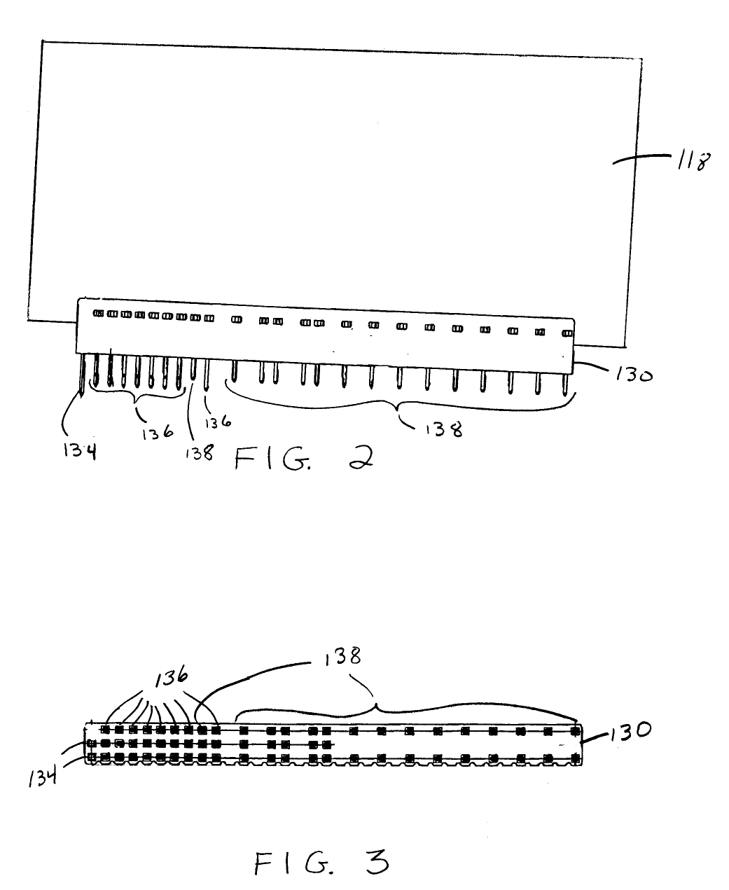

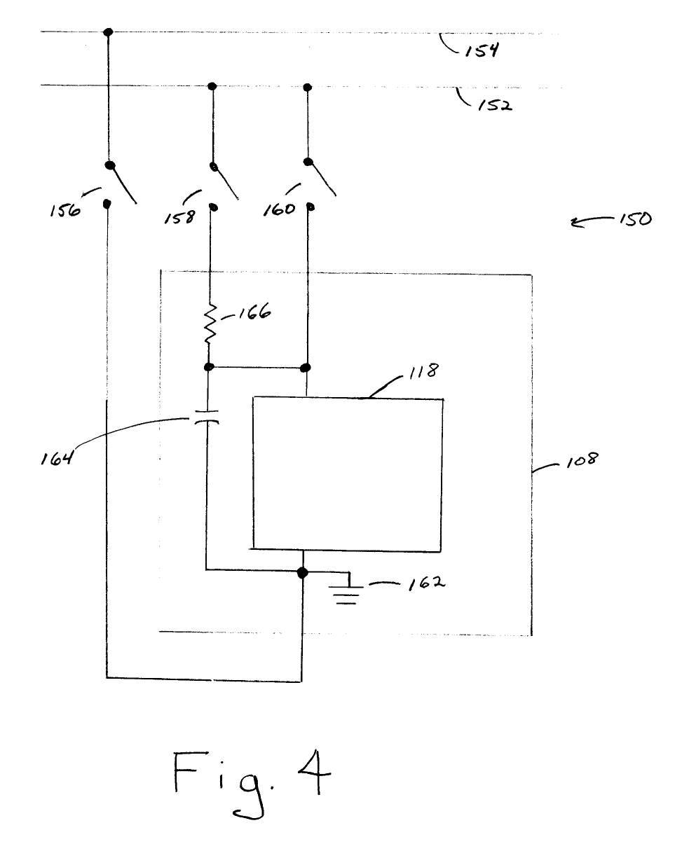

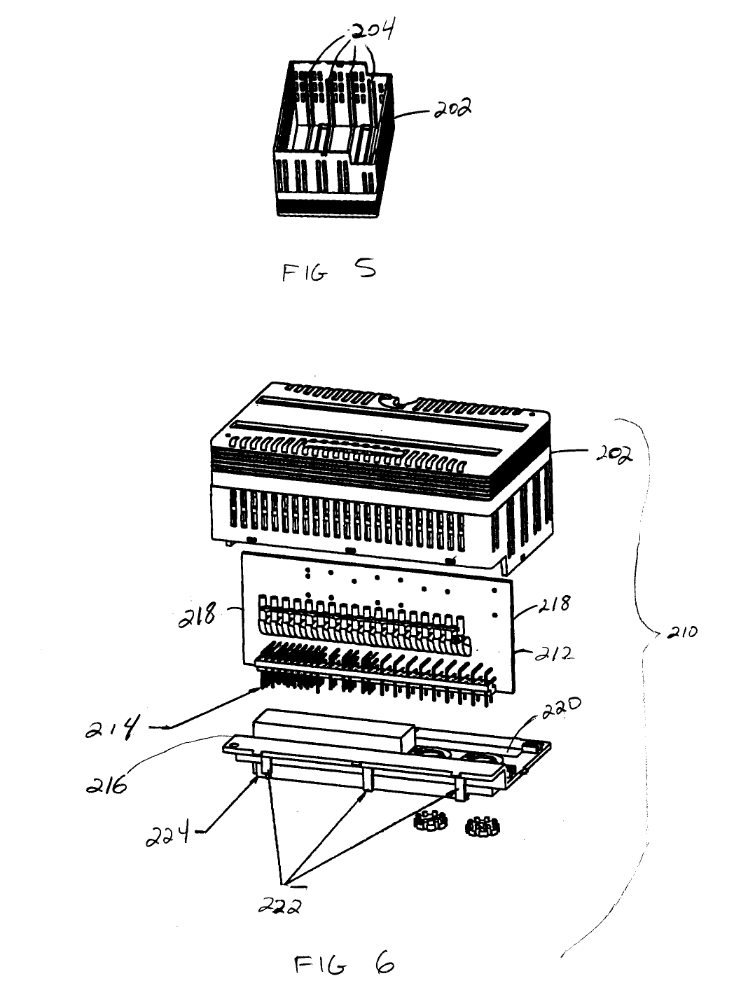

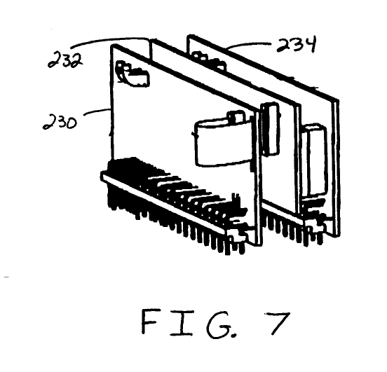

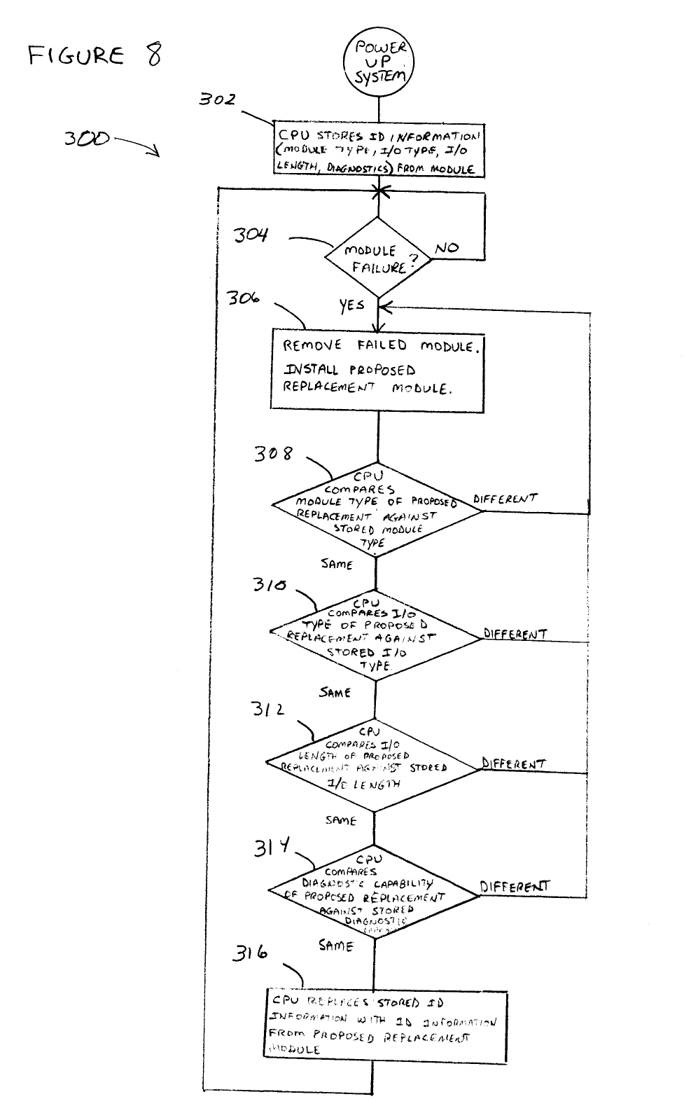

Figures 2 and 3 illustrate a side view of circuit card 118 and connector 130, and a bottom view of connector, 130 respectively. Connector 130 includes long length connector pins 134, medium length connector pins 136, and short length connector pins 138. As shown in Figure 3, one arrangement of pins 134, 136, and 138 is illustrated. In an alternative embodiment, pins 134, 136, and 138 could be arranged in an array having any desired shape and could be of the same diameter or different diameters. Connectors 124, 126, and 128 (shown in Figure 1) also include pins 134, 136, and 138.

Figure 4 is a schematic diagram illustrating a circuit 150, depicting the electrical effects of multi-length connector pins 134, 136, and 138 (shown in Figure 2). Power bus 120 (shown in Figure 1) typically includes at least two conductors, e.g., a voltage conductor 152 and a ground conductor 154. Long length pins 134 on circuit card connector 130 (shown in Figure 2) are represented by switch 156. Medium length pins 136 on circuit card connector 130 are represented by switch 158. Short pins 138 on circuit card connector 130 are represented by switch 160. As I/O module 108 (shown in Figure 1) is inserted into electronic system 100 (shown in Figure 1) long length pins 134 make electrical contact with ground conductor 154, represented schematically by switch 156 closing. Long length pins 134 connect to module ground 162. As I/O module 108 continues to be inserted into electronic system 100, medium length connector pins 136 make electrical contact with voltage conductor 152, represented schematically by switch 158 closing. As electrical contact is made, a capacitor 164, charges to a voltage of voltage conductor 152 buffered through a current limiting resistor 166 to begin power up of I/O circuit 118.

As circuit card 108 is inserted still further into electronic system 100, short length pins 138, represented by switch 160 closing, make electrical contact with voltage conductor 152, current limiting resistor 166 is bypassed and I/O circuit 118 is unbuffered, or directly connected to and powered by, voltage conductor 152. Current limiting resistor 166 limits capacitor 164 charge current, as I/O module 108 is inserted. Therefore any voltage drop that would be induced on power bus 120 by an instantaneous charging of a non-buffered capacitor and the application of power to I/O circuits 118 is reduced. As I/O module 108 continues to be inserted, and by the time short length pins 138 make electrical contact, capacitor 164 has been charged to the voltage of voltage conductor 152 of power bus 120 and thus almost no voltage drop is induced on voltage conductor 152 portion of power bus 120. In one embodiment, voltage conductor 152 portion of power bus 120 is electrically connected, or interfaced, to a voltage supply (not shown) of approximately 5 volts. In an alternative embodiment, the voltage conductor 152 portion of power bus 120 is electrically connected, or interfaced, to a voltage supply of approximately 3.3 volts.

Figure 5 illustrates a circuit module cover assembly 200 including a module cover 202 and a plurality of molded guide rails 204. As shown in Figure 6, circuit module 210, includes a module cover 202, a circuit card 212 employing multi-length connector pins 214, and a shroud 216. Molded guide rails 204 (shown in Figure 5) align circuit card 212 in module cover 202. Circuit card 212 includes two side edges 218, which slidably engage molded guide rails 204. Shroud 216 includes openings 220, a plurality of molded keys 220, and a connector shroud 224. Openings 220 allow connector pins 214 to be exposed for insertion into a system (not shown).

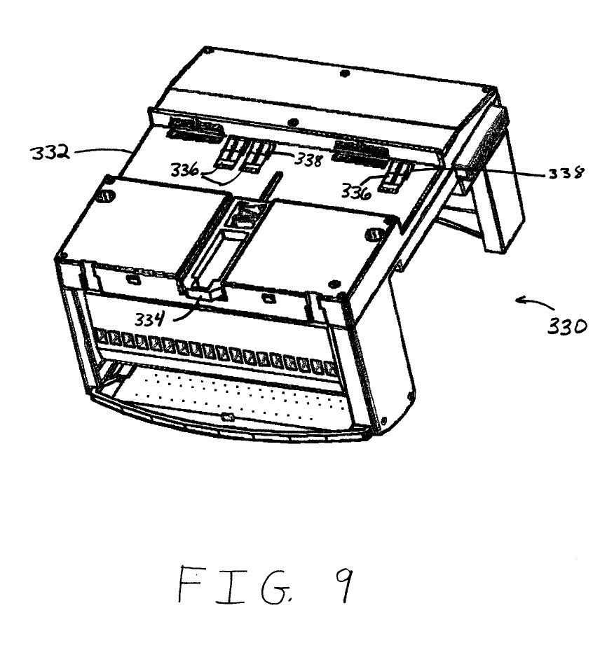

A circuit module 210 may include more than one circuit card. Figure 7 illustrates a plurality of circuit cards 230, 232, and 234 respectively. In one embodiment, circuit cards 230, 232, and 234 are configured to communicate with main CPU 132 (shown in Figure 1) resident in main module 102 (shown in Figure 1). When a circuit module including a plurality of circuit cards, 230, 232, and 234 for example, is replaced, mechanical alignment is not sufficient to prevent one circuit card 230, for example, from electrically engaging electronic system 100 (shown in Figure 1) before a second circuit card 234, for example, electrically engages electronic system 100 as well. In one embodiment, main CPU 132 in main module 102 (shown in Figure 1) is configured to recognize removal of an I/O module, such as I/O module 104 shown in Figure 1. Upon such recognition, main CPU 132 halts data communication with I/O module 104. Main CPU 132 is further configured to recognize insertion of an I/O module, such as I/O module 104, into electronic system 100 (shown in Figure 1) and will restart data communications. When the I/O module to be inserted includes a plurality of circuit cards 230, 232, and 234, for example, main CPU 132 is further configured to recognize electrical engagement of each circuit card 230, 232, and 234 with electronic system 100. Main CPU 132 is configured to not resume data communications with the I/O module containing the plurality of circuit cards 230, 232, and 234, for example, until all of circuit cards 230, 232, and 234 have electrically engaged electronic system 100. CPU 132 is configured to provide sufficient time for all of circuit cards 230, 232, and 234 to electrically engage electronic system 100 after recognizing that a first one of circuit cards 230, 232, or 234 has electrically engaged electronic system 100.

Figure 7 is a flowchart depicting operation of a module identification package 300. When power is applied to a typical electronic system including a CPU, such as main CPU 132 shown in Figure 1, the CPU reads, then stores, 302 data from each installed module. Examples of such data might include module type data, input/output (I/O) type data, I/O length data, and diagnostic capability. The CPU is configured to continuously verify proper operation of installed modules to determine 304 if a module has failed. After a failed module is detected, failed module is removed 306 and a proposed module for replacement is installed. Power to the system is never removed.

Once the proposed replacement module has been installed into an electronic system, such as electronic system 100 (shown in Figure 1), the CPU compares 308 stored module type data, for example, from the failed module with that of the proposed replacement module. An exemplary list of module type data includes discrete DC, discrete AC, analog, and intelligent. If module type data from the proposed replacement module matches module type data from the failed module, the CPU compares 310 stored I/O type data (input, output, combination input/output) from the failed module with I/O type data from the proposed replacement module. If I/O type data from the proposed replacement module, matches stored I/O type data from the failed module, the CPU compares 312 stored I/O length data from the failed module with I/O length data from the proposed replacement module. If I/O length data from the proposed replacement module matches stored I/O length data from the failed module, the CPU compares 314 stored diagnostic capability from the failed module with diagnostic capability of the proposed replacement module. If at any time data from the proposed replacement module does not match data of the failed module, the proposed replacement module is considered failed and the process is repeated using a different proposed replacement module. Otherwise, the CPU replaces 316 stored module identification data with module identification data from the proposed replacement module, which becomes part of the electronic system.

Figure 9 illustrates a bottom perspective view of an I/O module carrier 330 including a recessed area 332 and a sliding clip 334. Sliding clip 334 is for mounting I/O module carrier 330 on a mounting rail (not shown), for example, a DIN type rail carrier. Recessed area 332 includes a plurality of spring loaded pressure contacts 336 relative openings 338 in recessed area 332 of I/O module carrier 330. When I/O module carrier 330 is installed on the mounting rail, spring loaded pressure contacts 336 are compressed against the mounting rail into openings 338 to make electrical contact with I/O module carrier circuits (not shown). In one embodiment, the mounting rail is electrically connected to circuit ground and spring loaded pressure contacts 336 supply ground from the mounting rail to I/O module carrier 330 ground circuits.

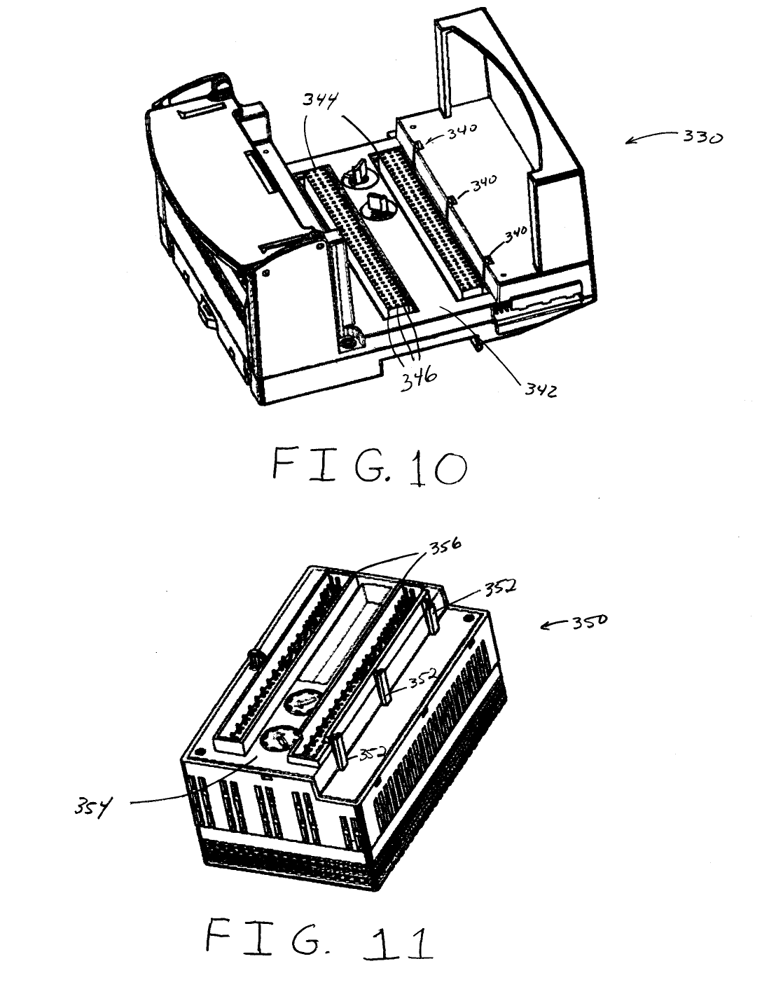

Figure 10 illustrates a bottom perspective view of I/O module carrier 330 including a plurality of T-shaped key slots 340. A module support surface 342 surrounds a pair of I/O module carrier connectors 344 which further include a plurality of contacts 346.

Figure 11 illustrates a perspective view of an I/O module 350. I/O module 350 includes a plurality of T-shaped keys 352 which are configured to slidably engage T-shaped key slots 340 (shown in Figure 9) when I/O module 350 is inserted into I/O module carrier 330 (shown in Figure 9). I/O module 350 further includes a carrier interface surface 354 and I/O module connectors 356. T-shaped key slots 340 and T-shaped keys 352 are configured so that when inserting I/O module 350 into I/O module carrier 330, module support surface 342 and carrier interface surface 354 are within approximately one degree of parallel to each other. Holding module support surface 342 and carrier interface surface 354 to within approximately one degree of parallel allows long length pins 132 (shown in Figure 2) to be the first set of pins to make contact with contacts 346 in I/O module carrier connectors 344 when I/O module carrier connectors 344 and I/O module connectors 356 engage. Further, medium length pins 134 (shown in Figure 2) are the second set of pins to make contact with contacts 346 in I/O module carrier connectors 344 and short length connector pins 136 are the last set of pins to make contact with contacts 346 in I/O module carrier connectors 344.

While the invention has been described in terms of various specific embodiments, those skilled in the art will recognize that the invention can be practiced with modification within the spirit scope of the claims. For example the slots and mating keys can have any shape as long as they slidably engage each other and hold the surfaces to within approximately one degree of parallel of each other. In addition, an I/O module and I/O module carrier can have more or less than two connectors.

Claims

1. A method for connecting a circuit module to a circuit module carrier, the circuit module carrier electrically connected to a powered electronic system, the circuit module including at least one circuit card and configured to slidably engage the circuit module carrier, said method comprising the steps of:
slidably engaging the circuit module and the circuit module carrier; and
inserting at least two connector pins of the circuit module, having different lengths into a connector of the circuit module carrier.

2. A method according to Claim 1 wherein said step of inserting at least two connector pins of the circuit module into a connector of the circuit module carrier further comprises the steps of:
inserting a first plurality of connector pins having a first length into the connector of the circuit module carrier; and
inserting a second plurality of connector pins having a second length into the connector of the circuit module carrier, the first length longer than the second length.

3. A method according to Claim 2 wherein said step of inserting a first plurality of connector pins of a first length into the connector of the circuit module carrier further comprises the step of connecting the first plurality of connector pins to a ground interface.

4. A method according to Claim 1 wherein said step of inserting a plurality of connector pins of the circuit module into the connector of the circuit module carrier further comprises the steps of:
inserting a first plurality of connector pins having a first length into the connector of the circuit module carrier;
inserting a second plurality of connector pins having a second length into the connector of the circuit module carrier, the first length longer than the second length; and
inserting a third plurality of connector pins having a third length into the connector of the circuit module carrier, the third length shorter than the first length and the second length.

5. A method according to Claim 4 wherein said step of inserting the first plurality of connector pins into the connector of the circuit module carrier further comprises the steps of connecting the first plurality of connector pins to a ground conductor, said step of inserting the second plurality of connector pins into the connector of the circuit module carrier further comprises the step of connecting the second plurality of connector pins to a voltage conductor interfaced to at least one of a voltage supply of 5 Volts and a voltage supply of 3.3 Volts.

6. A method according to Claim 4 wherein said step of inserting the first plurality of connector pins into the connector of the circuit module carrier further comprises the step of connecting the first plurality of connector pins to a ground conductor, said step of inserting the second plurality of connector pins into the connector of the circuit module carrier further comprises the step of connecting the second plurality of connector pins to a buffered voltage conductor interfaced to a voltage supply of 5 Volts, said step of inserting the third plurality of connector pins into the connector of the circuit module carrier further comprises the step of connecting the third plurality of connector pins to an unbuffered voltage conductor interfaced to a voltage supply of 5 Volts.

7. A method according to Claim 4 wherein said step of inserting the first plurality of connector pins into the connector of the circuit module carrier further comprises the step of connecting the first plurality of connector pins to a ground conductor, said step of inserting the second plurality of connector pins into the connector of the circuit module carrier further comprises the step of connecting the second plurality of connector pins to a buffered voltage conductor interfaced to a voltage supply of 3.3 Volts, said step of inserting the third plurality of connector pins into the connector of the circuit module carrier further comprises the step of connecting the third plurality of connector pins to an unbuffered voltage conductor interfaced to a voltage supply of 3.3 Volts.

8. A method according to Claim 1 wherein said step of slidably engaging the circuit module and the circuit module carrier further comprises the step of:
attaching at least one key on the circuit module within a key slot on the module carrier so that mating surfaces of the module and module carrier are within one degree of being parallel to each other.

9. A method according to Claim 1 wherein said step of slidably engaging the circuit module and the circuit module carrier further comprises the step of:
attaching at least one T shaped key on the circuit module within a corresponding key slot on the module carrier so that mating surfaces of the module and module carrier are within one degree of being parallel to each other.

10. A method according to Claim 1 wherein the electronic system includes a CPU, said method further comprising the steps of:
configuring the CPU with a module identification package to detect insertion of a circuit module into the electronic system and compare module identification data for the inserted circuit module with previously stored module identification data for a previously removed circuit module; and
replacing stored module identification data with module identification data from the inserted circuit module if the module identification data for the inserted circuit module and the previously removed circuit module matches.

11. A method according to Claim 10 wherein said step of configuring the CPU with a module identification package further comprises the step of configuring the CPU to compare module type data, input/output type data, length of input/output data, and diagnostic information from the module.

12. A method according to Claim 11 wherein said step of comparing module type data further comprises the step of determining if the module type data is one of discrete DC, discrete AC, analog, and intelligent.

13. A method according to Claim 11 wherein said step of comparing input/output type data further comprises the step of determining if the input/output type data is one of input, output, and combination input/output.

14. A connector apparatus for insertion into an electronic system powered and running, said apparatus comprising:
at least one connector comprising a first plurality of connector pins having a first length and a second plurality of connector pins having a second length, said first length longer than said second length; and
at least one key configured to slidably engage a key slot when inserting said connector apparatus into the electronic system.

15. A connector apparatus according to Claim 14 wherein said first plurality of connector pins connect to a ground interface.

16. A connector apparatus according to Claim 14 wherein said second plurality of connector pins connect to at least one of a 5 Volt interface and a 3.3 Volt interface.

17. A connector apparatus according to Claim 14 wherein said connector module further comprises a third plurality of connector pins having a third length, said third length shorter than said first length and said second length.

18. A connector apparatus according to Claim 17 wherein said third plurality of connector pins connect to at least one of an unbuffered 5 Volt interface and an unbuffered 3.3 Volt interface.

19. A connector apparatus according to Claim 14 wherein said at least one key has a "T" shape.

20. A connector apparatus according to Claim 14 wherein said at least one key is configured so that said connector apparatus and corresponding mating connectors of the electronic system slidably engage each other within one degree of parallel of one another.

21. A method for replacing multiple circuit cards within a powered electronic system, the electronic system comprising a power supply, a central processing unit, and at least one circuit module interface slot, said method comprising the steps of:
configuring the circuit module interface to accept circuit modules including at least two circuit cards; and
configuring the central processing unit to allow insertion and removal of circuit modules when said power supply is supplying power to the circuit modules.

22. A method according to Claim 21 wherein said step of configuring the central processing unit to allow insertion and removal of circuit modules when the power supply is supplying power to the circuit modules further comprises the steps of:
sensing removal of a circuit module;
halting data communications with the circuit module;
recognizing when a replacement circuit module has been inserted into the electronic system; and
restarting data communications with the circuit module.

23. A method according to Claim 22 wherein said step of recognizing when a replacement circuit module has been inserted into the electronic system further comprises the steps of:
configuring the central processing unit to recognize when an inserted circuit module contains more than one circuit card; and
delaying the restart of data communications with the replacement circuit module until all circuit cards within the replacement circuit module have electrically engaged the electronic system.

24. An electronic system comprising:
a power supply;
at least one circuit module interface slot configured to accept circuit modules including at least two circuit cards;
at least one circuit module; and
a central processing unit; configured to allow insertion and removal of circuit modules when said power supply is supplying power to said circuit modules.

25. An electronic system according to Claim 24 wherein said central processing unit is further configured to:
sense removal of said circuit module;
halt data communications with said circuit module;
recognize when a replacement circuit module has been inserted into said electronic system; and
restart data communications with said circuit module.

26. An electronic system according to Claim 25 wherein said central processing unit is further configured to:
recognize when a replacement module contains more than one circuit card; and
wait until all circuit cards within said circuit module have electrically engaged said electronic system before restarting data communications with said circuit module.
